(19) United States
(12) Patent Application Publication
(10) Pub. No.: US 2023/0126459 A1
(43) Pub. Date: Apr. 27, 2023

(54) RING STRUCTURE WITH COMPLIANT CENTERING FINGERS

(71) Applicant: Lam Research Corporation, Fremont, CA (US)

(72) Inventors: Gary Bridger Lind, Penn Valley, CA (US); Jeremy Todd Tucker, Mountain View, CA (US)

(21) Appl. No.: 17/905,628

(22) PCT Filed: Mar. 2, 2021
(86) PCT No.: PCT/US2021/070218

§ 371 Date: Sep. 2, 2022

Related U.S. Application Data
(60) Provisional application No. 62/986,320, filed on Mar. 6, 2020.

(51) Int. Cl. H01L 21/687

(52) U.S. Cl. CPC H01L 21/68721

(57) ABSTRACT

Improved edge rings with wafer-centering roller mechanisms are disclosed. The roller mechanisms of these apparatuses are equipped with spring-biased rollers that are urged radially inward such that the rollers may move radially inward or outward to compensate for differential temperature expansion between wafers and the edge ring over a large temperature range while still maintaining high placement accuracy at both high and low temperatures.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

It is often desirable to protect the edge of a semiconductor wafer during processing operations to prevent undesirable deposition or etching on the edges and/or the underside of the semiconductor wafer. One technology that is used to provide such edge protection is what is commonly referred to in the industry as a “exclusion ring” or “edge ring”.

A typical edge ring features a ring structure that has an opening in the middle that is sized slightly smaller than the diameter of the semiconductor wafers with which it is to be used, such that when the edge ring is placed over, and centered on, the semiconductor wafer, the inner edge of the edge ring overlaps the exterior edge of the semiconductor wafer by some small amount.

Some edge ring designs feature three roller mechanisms that are located 120°±10° apart from each other about the circumference of the ring structure; these roller mechanisms include rollers that are positioned such that the innermost portions thereof define a circle that is nominally the same diameter (or within some tolerance limit thereof) as that of the semiconductor wafers with which the edge ring is to be used. In other implementations, the roller mechanisms may be spaced apart by other amounts. In some such implementations, the roller mechanisms may be spaced apart asymmetrically, e.g., 100°, 100°, and 160°, to allow for increased clearance to allow a wafer to be inserted therein, e.g., through the side of the edge ring that has the 160° angular spacing between roller mechanisms. Such spacings may allow for shorter-length cantilever beam structures, or fingers, for supporting the rollers to be used, thereby reducing the impact that such structures may have on various process chamber characteristics, e.g., gas flow. The roller mechanisms additionally include contact pads that are positioned radially inward from the rollers. The rollers and the contact pads are spaced vertically downward from the underside of the ring structure, forming a cradle underneath the ring structure that can receive and support a semiconductor wafer. During wafer loading operations, such an edge ring, which is typically pre-positioned at a chuck within a semiconductor processing chamber, may be raised clear of the chuck. A wafer handling robot end effector supporting a semiconductor wafer may then be controlled to insert the semiconductor wafer into the edge ring in the gap between rollers and the underside of the ring structure. The semiconductor wafer may, during such insertion, be placed in a location that, in theory, is centered on the edge ring. Once placed, the semiconductor wafer may be lowered (or the edge ring raised) so as to cause the semiconductor wafer to be placed on the contact pads of the roller mechanisms. During such vertical relative movement between the semiconductor wafer and the edge ring, one or more of the rollers may, if the semiconductor wafer and edge ring are not sufficiently centered with respect to one another, engage the edge of the semiconductor wafer and cause the semiconductor wafer to displace laterally so as to be more accurately centered. Once the semiconductor wafer is lowered onto the contact pads (and the wafer handling robot end effector withdrawn), the edge ring (and semiconductor wafer) may be lowered into the chuck. When the semiconductor wafer contacts the chuck, the chuck will lift the semiconductor wafer off of the edge ring contact pads. The roller mechanisms of the edge ring will continue to be lowered into recesses in the chuck until the ring structure of the edge ring is supported by the chuck as well. Centering devices within the chuck that engage with the edge ring ensure that the edge ring is centered on the chuck. Such edge rings thus allow the semiconductor wafer, edge ring, and chuck to all be generally centered with respect to one another.

This disclosure pertains to improvements of edge rings having roller mechanisms; references below to edge rings are to be understood to be directed generally to such types of edge rings.

### SUMMARY

Details of one or more implementations of the subject matter described in this specification are set forth in the accompanying drawings and the description below. Other features, aspects, and advantages will become apparent from the description, the drawings, and the claims.

The present inventors determined that conventional edge ring designs featuring roller mechanisms, which have been used for over twenty years in the industry, would suffer from an unrecognized issue in some circumstances, and developed enhanced edge ring designs to eliminate such issues. The inventors determined that conventional edge ring designs were not usable in certain semiconductor processes due to the complex interplay between thermal expansion coefficient mismatches, large processing temperature ranges, and reduced levels of permissible edge ring wafer edge overlap. In particular, there is a general tendency in the semiconductor manufacturing industry to increase wafer yield by utilizing more and more of the wafer area. In order to maximize the area of the wafer that may be effectively used for die production, manufacturers have been increasingly requiring that the degree of overlap allowed between an edge ring and the edge of the semiconductor wafer be reduced from previous levels. Since the area of the semiconductor wafer that is overlapped by the edge ring is effectively unable to be processed, this overlap area essentially represents a portion of the semiconductor wafer that cannot be used to increase die yield from the semiconductor wafer. By reducing the overlap area, the area of the semiconductor wafer usable for die production is increased, thereby increasing yield.

In order to maintain adequate edge protection using an edge ring, however, it is desirable to ensure that the edge ring overlaps the semiconductor wafer that it protects around the entire circumference thereof. As the extent of permissible overlap is decreased, the edge ring and the semiconductor wafer must correspondingly be centered more accurately relative to each other to ensure that the edge ring overlaps the semiconductor wafer around the entire perimeter thereof. In order to achieve such increased accuracy, the rollers of the roller mechanisms of such edge rings must be positioned such that their innermost surfaces define a circle that is closer to the diameter of the semiconductor wafer than was needed prior to the introduction of such more stringent overlap requirements. By positioning the rollers such that a smaller circle is defined by the innermost surfaces thereof, the rollers are caused to increase the accuracy of the wafer centering function that they provide.

The present inventors additionally discovered, however, that positioning the rollers in such a manner introduced significant issues in certain use cases involving large temperature differentials. Semiconductor wafers are typically made of silicon, whereas edge rings are typically made of a ceramic, such as aluminum oxide. As a result, a semiconductor wafer may experience thermal expansion that is less than a third that experienced by an edge ring that supports it. While this is not necessarily an issue when the edge ring and the semiconductor wafer always interact under the same temperature conditions, it presents serious issues with edge rings that are designed to provide the enhanced accuracy noted above under extreme temperature variations, e.g., temperature changes of several hundred degrees Celsius.

In such instances, adequate centering accuracy may only be achievable at one of the two temperature extremes. At the other temperature extreme, the required centering accuracy may not be achievable and, in some cases, damage to the semiconductor wafer may occur.

For example, if the rollers are positioned such that they define a circle of 300 mm diameter (a typical nominal wafer diameter) when the edge ring is at room temperature, e.g., 20° C., this would, in theory, center a 300 mm diameter wafer relative to the edge ring at that temperature. If the edge ring is heated to a temperature of 420° C., however, the edge ring (assuming it is generally made entirely of aluminum oxide) would expand such that the circle defined by the innermost surfaces of the rollers of the edge ring has a diameter of 300.972 mm (400° C.·8.1×10⁻⁶ C⁻¹·300 mm=0.972 mm of thermal expansion beyond the original 300 mm). At the same time, the semiconductor wafer (assuming it is made of silicon) would expand under the same conditions to a diameter of 300.312 mm (400° C.·2.6×10⁻⁶ C⁻¹·300 mm=0.312 mm of thermal expansion beyond the original 300 mm). There would thus be approximately two thirds of a millimeter of play between the rollers and the semiconductor wafer at 420° C., allowing for the semiconductor wafer and the edge ring to be off-center relative to each other by at least a third of a millimeter when the edge ring is in contact with at least one of the rollers, which may exceed the desired radial width of the overlap area between the edge ring and the semiconductor wafer for a given semiconductor process.

If the same edge ring is instead designed such that the rollers define a 300.312 mm circle at the elevated temperature of 420° C., thereby providing theoretically perfect centering of the nominal 300 mm diameter (at room temperature) semiconductor wafer at the higher end of the example temperature range, the circle defined by those same rollers when the edge ring is at room temperature will be smaller than the diameter of the semiconductor wafer under the same conditions. For example, the innermost surfaces of the rollers may, at room temperature, define a circle with a diameter of 299.339 mm (400° C.·8.1×10⁻⁶ C⁻¹·300 mm=0.973 mm of thermal contraction from the original 300 mm), whereas the diameter of the semiconductor wafer at that temperature may be 300 mm. This size mismatch may cause the semiconductor wafer to not be able to fit between the rollers, causing the semiconductor wafer to become jammed between the rollers or otherwise prevented from sitting flat on the contact pads of the edge ring. In the extreme case, the semiconductor wafer may, if it is able to be supported by the contact pads in such circumstances, be subjected to a radial compressive load due to the interference fit between the semiconductor wafer and the rollers. Such loading may overstress the semiconductor wafer and cause it to fracture or otherwise become damaged.

Having identified this potential issue, which had not previously been appreciated in view of the centering tolerances that have long been in use in the industry, the present inventors conceived of improved edge ring designs in which the roller mechanisms of such edge rings featured a spring-biased roller, i.e., a roller that is configured to be radially translatable and that is urged radially inward by a spring element of some kind. The present inventors further conceived of roller mechanism designs that were compatible with existing roller mechanisms in terms of packaging constraints, thereby allowing the new, enhanced edge ring rings to be used with existing semiconductor processing tools with no modifications to the semiconductor processing tools.

The discussion below, as well as the Figures, provide details on several different embodiments of such improved edge ring rings, although it will be appreciated that other implementations of a similar nature but differing various details are within the scope of this disclosure as well. The normal operation and structure of a standard edge ring are not discussed below in great detail, although U.S. Pat. No. 6,126,382, which is hereby incorporated herein by reference in its entirety, provides a thorough discussion of an example edge ring with reference to FIGS. 10-16 thereof if the reader desires further information as to the interaction of an edge ring with a semiconductor processing tool and semiconductor wafer. The manner in which the improved edge rings discussed herein are used with respect to their installation and interfacing with semiconductor processing tools would be similar to that described for the standard edge rings of U.S. Pat. No. 6,126,382, i.e., the additional functionality provided by the improved edge rings discussed herein can be taken advantage of without requiring additional hardware on the semiconductor processing tool or operational changes to how the semiconductor processing tool interfaces with such improved edge rings.

In some implementations, an apparatus may be provided that includes a ring structure having an inner perimeter and an outer perimeter. The inner perimeter may define a circular opening having a first diameter and a ring center axis. The apparatus may further include a plurality of roller mechanisms that are connected with the ring structure and positioned at locations along a reference circle centered on the ring center axis. Each such roller mechanism may have a non-compliant support structure, a roller configured to rotate about a corresponding axis of rotation relative to the non-compliant support structure of that roller mechanism, and a spring element configured to urge the roller for that roller mechanism radially inward with respect to the ring center axis. In such implementations, the non-compliant support structure of that roller mechanism spaces the roller of that roller mechanism apart from the ring structure such that the roller of that roller mechanism does not overlap with the ring structure when viewed along an axis perpendicular to the ring center axis.

In some implementations of the apparatus, the spring element may be a coil spring, cantilevered beam spring, or a leaf spring.

In some implementations of the apparatus, the minimum distance between the non-compliant support structures of at least two of the roller mechanisms may be larger than a first distance, the inner perimeter may be circular and have a diameter that is less than the first distance, and the first distance may be 200 mm, 300 mm, or 450 mm.

In some implementations of the apparatus, the rollers may all be positioned entirely outside of the inner perimeter when viewed along the ring center axis.

In some implementations of the apparatus, there may be three roller mechanisms that are spaced at locations 120°±10° apart from one another about the ring center axis.

In some implementations of the apparatus, each roller mechanism may further include an axle and a yoke. The yoke of each roller mechanism may engage the axle of that roller mechanism, the axle of that roller mechanism may support the roller of that roller mechanism, and the spring element of that roller mechanism may be configured to apply a force to the yoke of that roller mechanism that urges the yoke of that roller mechanism, and thus the axle of that roller mechanism and the roller of that roller mechanism, radially inward with respect to the ring center axis.

In some implementations of the apparatus, each roller mechanism may further include a cantilever beam structure having a first end and a second end. For each roller mechanism of such implementations, the first end of the cantilever beam structure of that roller mechanism may be connected with the non-compliant support structure of that roller mechanism, the second end of the cantilever beam structure of that roller mechanism may be located radially inward from the first end of the cantilever beam structure of that roller mechanism, and the roller of that roller mechanism may be located at the second end of the cantilever beam structure for that roller mechanism.

In some implementations of the apparatus, the cantilever beam structure of each roller mechanism may have a slot extending along a corresponding slot axis that extend along a radial direction relative to the ring center axis, and the axle of that roller mechanism may be located within the slot in the cantilever beam structure of that roller mechanism.

In some implementations of the apparatus, the cantilever beam structure of each roller mechanism may have a minimum contact area feature disposed at the second end thereof, the minimum contact area feature of the cantilever beam structure of that roller mechanism may be configured to contact an underside of a wafer when the wafer is lowered onto the cantilever beam structures, and the minimum contact area feature of the cantilever beam structure of that roller mechanism may be located closer to the ring center axis than the roller of that roller mechanism.

In some implementations of the apparatus, at least the cantilever beam structure of each roller mechanism may include a corresponding bore that extends along a corresponding bore axis that extends along a radial direction relative to the ring center axis, and the spring element may be a coil spring that is located at least partially within the bore.

In some implementations of the apparatus, the axle for each roller mechanism may have a length along the corresponding axis of rotation for the roller of that roller mechanism that is less than a width of the yoke for that roller mechanism along the corresponding axis of rotation for the roller for that roller mechanism, the roller for that roller mechanism may have a width along the corresponding axis of rotation of that roller that is less than the width of the yoke for that roller mechanism along the corresponding axis of rotation of that roller, the yoke for that roller mechanism may have two protruding portions that overlap both the roller and the axle for that roller mechanism when viewed along the corresponding axis of rotation for the roller of that roller mechanism, and both the roller and the axle for that roller mechanism may be interposed between the two protruding portions of the yoke for that roller mechanism.

In some implementations of the apparatus, the coil spring may be made of nickel or a nickel-dominant alloy.

In some implementations of the apparatus, the coil spring may be made of a ceramic material.

In some implementations of the apparatus, each roller mechanism may further include a cantilever beam spring and, for each roller mechanism, a first end of the cantilever beam spring of that roller mechanism may be interfaced with a portion of the non-compliant support structure of that roller mechanism, a second end of the cantilever beam spring of that roller mechanism may be interfaced with the yoke of that roller mechanism, and the cantilever beam spring of that roller mechanism may be configured to bend when the yoke of that roller mechanism is translated radially outward relative to the ring center axis.

In some implementations of the apparatus, the cantilever beam spring may be a hollow tube.

In some implementations of the apparatus, the cantilever beam spring may be a ceramic capillary tube.

In some implementations of the apparatus, the cantilever beam spring of each roller mechanism may be interfaced with a first end of the yoke of that roller mechanism, and a second end of the yoke of that roller mechanism opposite the first end of the yoke of that roller mechanism may include an axle interface that is configured to rotatably support the axle of that roller mechanism.

In some implementations of the apparatus, each roller mechanism may further include a leaf spring and, for each roller mechanism, the leaf spring of that roller mechanism may be located within that roller mechanism such that a major face of the leaf spring of that roller mechanism is generally parallel to the ring center axis, and the yoke of that roller mechanism may have a first end that is positioned so as to transmit force to the leaf spring of that roller mechanism when the yoke of that roller mechanism is translated radially outward relative to the ring center axis.

In some implementations of the apparatus, the leaf spring of each roller mechanism may be supported in the radial direction relative to the ring center axis by two spaced-apart support features of that roller mechanism, the first end of the yoke of that roller mechanism may be configured to contact the leaf spring of that roller mechanism at a location on an opposite side of the leaf spring of that roller mechanism that is supported by the spaced-apart support features of that roller mechanism, and the first end of the yoke of that roller mechanism may be further configured to contact the leaf spring of that roller mechanism midway between the spaced-apart support features of that roller mechanism.

In some implementations, an apparatus may be provided that includes a ring structure having a circular opening defining a ring center axis. The apparatus may further include a plurality of roller mechanisms that are connected with the ring structure, each roller mechanism having: a) a non-compliant support structure, b) an axle, c) a roller configured to rotate about a corresponding axis of rotation relative to the non-compliant support structure of that roller mechanism and supported by the axle within that roller mechanism, d) a cantilever beam structure extending inward from the non-compliant support structure of that roller mechanism towards the ring center axis, and e) a spring element configured to urge the axle for that roller mechanism toward the ring center axis. In such implementations, the cantilever beam structure of that roller mechanism may have a slot at a radially inward end and having length along a radial direction relative to the ring center axis and a width along a direction parallel to the ring center axis, the length of the slot of that roller mechanism may be larger than the width of the slot of that roller mechanism, and the width of the slot of that roller mechanism may be larger than the axle of that roller mechanism. In such implementations, the roller of that roller mechanism may be positioned such that that roller mechanism does not overlap with the ring structure when viewed along an axis perpendicular to the ring center axis.

In some implementations of the apparatus, the spring element is a coil spring, a cantilevered beam spring, or a leaf spring.

In some implementations of the apparatus, the minimum distance between the non-compliant support structures of at least two of the roller mechanisms may be larger than a first distance, the circular opening may have a diameter that is less than the first distance, and the first distance may be 200 mm, 300 mm, or 450 mm.

In some implementations of the apparatus, the rollers may all be positioned entirely outside of the circular opening when viewed along the ring center axis.

In some implementations of the apparatus, there may be three roller mechanisms that are spaced at locations 120°±10° apart from one another about the ring center axis.

In some implementations of the apparatus, each roller mechanism may further include a yoke, the yoke of that roller mechanism may engage the axle of that roller mechanism, and the spring element of that roller mechanism may be configured to apply a force to the yoke of that roller mechanism that urges the yoke of that roller mechanism, and thus the axle of that roller mechanism and the roller of that roller mechanism towards the ring center axis.

In some implementations of the apparatus, the cantilever beam structure of each roller mechanism may have a minimum contact area feature disposed at an end thereof that is closest to the ring center axis and the minimum contact area feature of the cantilever beam structure of that roller mechanism may be located closer to the ring center axis than the roller of that roller mechanism.

In some implementations of the apparatus, at least the cantilever beam structure of each roller mechanism may include a corresponding bore that extends along a corresponding bore axis that extends along a radial direction relative to the ring center axis, and the spring element of that roller mechanism may be a coil spring that is located at least partially within the bore.

In some such implementations of the apparatus, the axle for each roller mechanism may have a length along the corresponding axis of rotation for the roller of that roller mechanism that is less than a width of the yoke for that roller mechanism along the corresponding axis of rotation for the roller for that roller mechanism, the roller for that roller mechanism may have a width along the corresponding axis of rotation of that roller that is less than the width of the yoke for that roller mechanism along the corresponding axis of rotation of that roller, the yoke for that roller mechanism may have two protruding portions that overlap both the roller and the axle for that roller mechanism when viewed along the corresponding axis of rotation for the roller of that roller mechanism, and both the roller and the axle for that roller mechanism may be interposed between the two protruding portions of the yoke for that roller mechanism.

In some alternative or additional such implementations of the apparatus, the coil spring may be made of nickel or a nickel-dominant alloy or of a ceramic material.

In some implementations of the apparatus, each roller mechanism may further include a cantilever beam spring and, for each roller mechanism, a first end of the cantilever beam spring of that roller mechanism may be interfaced with a portion of the non-compliant support structure of that roller mechanism, a second end of the cantilever beam spring of that roller mechanism may be interfaced with the yoke of that roller mechanism, and the cantilever beam spring of that roller mechanism may be configured to bend when the yoke of that roller mechanism is translated radially outward relative to the ring center axis.

In some such implementations of the apparatus, the cantilever beam spring may be a hollow tube, e.g., a ceramic capillary tube.

In some implementations of the apparatus, the cantilever beam spring of each roller mechanism may be interfaced with a first end of the yoke of that roller mechanism, and a second end of the yoke of that roller mechanism opposite the first end of the yoke of that roller mechanism may include an axle interface that is configured to rotatably support the axle of that roller mechanism.

In some implementations of the apparatus, each roller mechanism may further include a leaf spring. In such implementations, the yoke of that roller mechanism may have a first end that is positioned so as to deflect the leaf spring of that roller mechanism when the yoke of that roller mechanism is translated radially outward relative to the ring center axis.

In some such implementations of the apparatus, the leaf spring of each roller mechanism may have a first side that is supported by two spaced-apart support features of that roller mechanism, and the first end of the yoke of that roller mechanism may be configured to contact a second side of the leaf spring of that roller mechanism opposite the first side of that leaf spring at a location midway between the spaced-apart support features of that roller mechanism.

These and other implementations will be discussed in more detail below.

### BRIEF DESCRIPTION OF THE DRAWINGS

FIG. 1 depicts an isometric view of an example edge ring according to the present disclosure.

FIG. 2 depicts an isometric view of the underside of the example edge ring of FIG. 1 but with a wafer placed within the edge ring.

FIG. 3 is a top view of the example edge ring of FIG. 1.

FIG. 4 is an exploded isometric view of the example edge ring of FIG. 1.

FIGS. 5A through 5D are a cross-sectional side view, a cross-sectional top view, an isometric section view, and an exploded isometric view, respectively, of an example roller mechanism for an edge ring.

FIGS. 6A through 6C depict cross-sectional broken side views of the edge ring of FIG. 1 during various stages of wafer placement in the edge ring.

FIGS. 7A through 7C are a cross-sectional side view, a cross-sectional top view, and an exploded isometric view, respectively, of another example roller mechanism for an edge ring.

FIGS. 8A through 8C are a cross-sectional side view, a cross-sectional top view, and an exploded isometric view, respectively, of yet another example roller mechanism for an edge ring.

FIG. 9 depicts four different roller mechanisms—three roller mechanisms with spring-biased rollers as well as a fourth non-spring-biased roller mechanism for a conventional edge ring.

### DETAILED DESCRIPTION

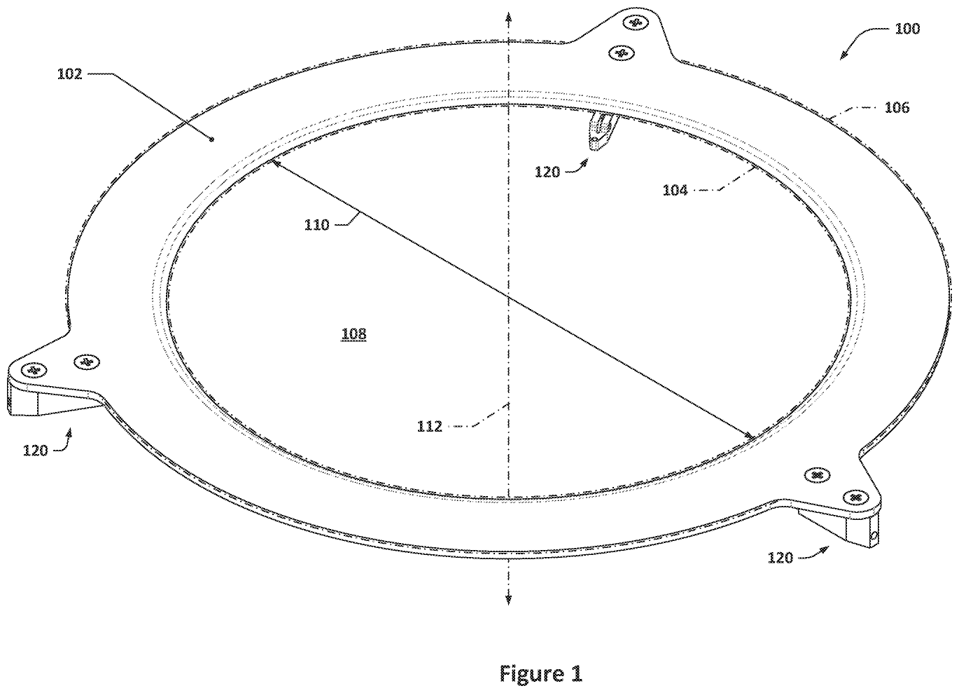

FIG. 1 depicts an isometric view of an example edge ring according to the present disclosure. In FIG. 1, an apparatus 100, which may be an edge ring, is shown that has a ring structure 102 and three roller mechanisms 120 connected therewith. The roller mechanisms 120 are positioned equidistantly apart around the circumference of the ring structure 102. The ring structure 102 may have an inner perimeter 104 that defines a circular opening 108 in the middle that has a first diameter 110. The circular opening 108 may be centered on a ring center axis 112. The ring structure 102 may also have an outer perimeter 106; in some implementations, the ring structure may also have peninsulas or protrusions in the outer perimeter 106 to accommodate mounting of the roller mechanisms 120, e.g., as shown in FIG. 1.

It will be understood that in some edge rings, the circular opening 108 may feature one or more small protrusions that extend radially inward from the innermost edge of the edge ring by a small distance; such a protrusion feature or features may be positioned such that they overlap with a corresponding notch feature or features on the perimeter of a wafer. For example, a 300 mm wafer may have a small, e.g., 1 mm or 1.5 mm radius, semicircular notch on the outer edge of the wafer that serve as an indexing fiducial to allow the rotational orientation of the wafer to be determined. In some edge rings that may be used with such wafers, the edge ring may include a protrusion feature that is sized so as to cover most or all of the notch area when the edge ring is centered on the wafer and rotationally oriented so that the wafer notch and the protrusion feature line up. Such protrusion features, in the context of this disclosure, are to be understood as not affecting the circularity of the interior edge of an edge ring. In other words, the presence of one or more such protrusion features along the interior edge of an edge ring does not render that edge ring's interior edge non-circular.

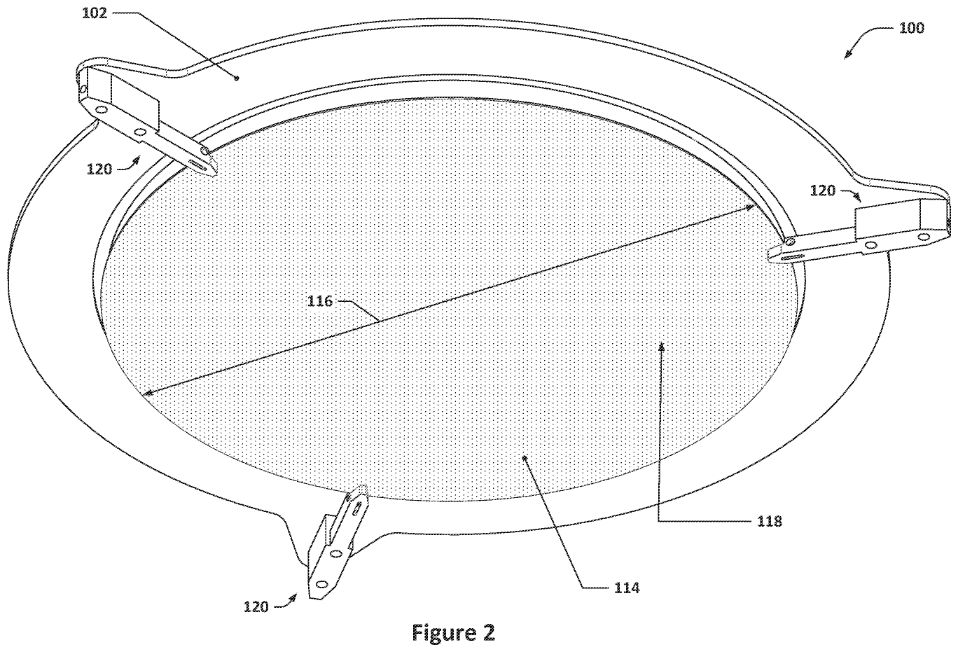

Consistent with earlier discussions of edge rings, the roller mechanisms 120 of the apparatus 100 of FIG. 1 may receive a wafer (for ease of reference, “wafer” and “semiconductor wafer” may be used interchangeably in this discussion). FIG. 2 depicts an isometric view of the underside of the example edge ring of FIG. 1 but with a wafer placed within the edge ring. As can be seen, wafer 114 has been placed on the roller mechanisms 120 such that the underside 118 of the wafer 114 rests on minimum contact area (MCA) features (not shown in FIG. 2 but visible in later Figures) of the roller mechanisms. It will be understood that MCAs are features, typically with rounded or partial spherical surfaces, that are configured to contact the underside of a wafer with a minimum or near-minimum amount of actual contact. The wafer 114 may have a nominal diameter 116; common such nominal diameters in the industry are 200 mm and 300 mm, although 450 mm diameter wafers have also been contemplated, and the apparatuses disclosed herein are usable with other sizes of wafer as well.

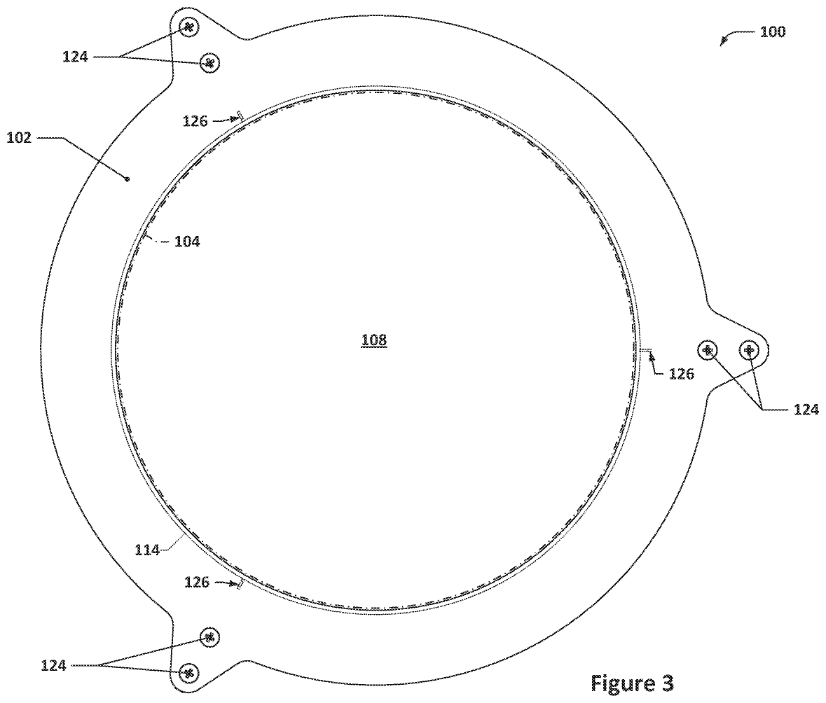

FIG. 3 is a top view of the example edge ring of FIG. 1. As can be seen, rollers 126 are represented by dotted outlines, as they are positioned beneath the ring structure 102. Also shown is a dotted outline representing the wafer 114, which is inscribed within the innermost surfaces of the rollers 126, i.e., centered between the rollers 126 (and within the ring structure 102). Screws 124 are also visible; the screws 124 may be used to attach the roller mechanisms 120 to the ring structure 102. As can be seen, the rollers 126 are all located entirely outside of the inner perimeter 104. Similarly, the outer edge of the wafer 114 is also located entirely outside of the inner perimeter 104 of the ring structure 102, thereby ensuring that the ring structure 102 overlaps the wafer 114 around its entire perimeter. It will be noted that some wafers may have a notch or other indexing feature that may be used to identify the orientation of the wafer through various semiconductor processing stages. Such a notch may, in some implementations, extend radially inward past the inner perimeter 104, resulting in a small portion of the notch that is not overlapped by the ring structure 102; the ring structure 102 may nonetheless still be considered, for the purposes of this discussion, to overlap the entire outer perimeter of the wafer 114.

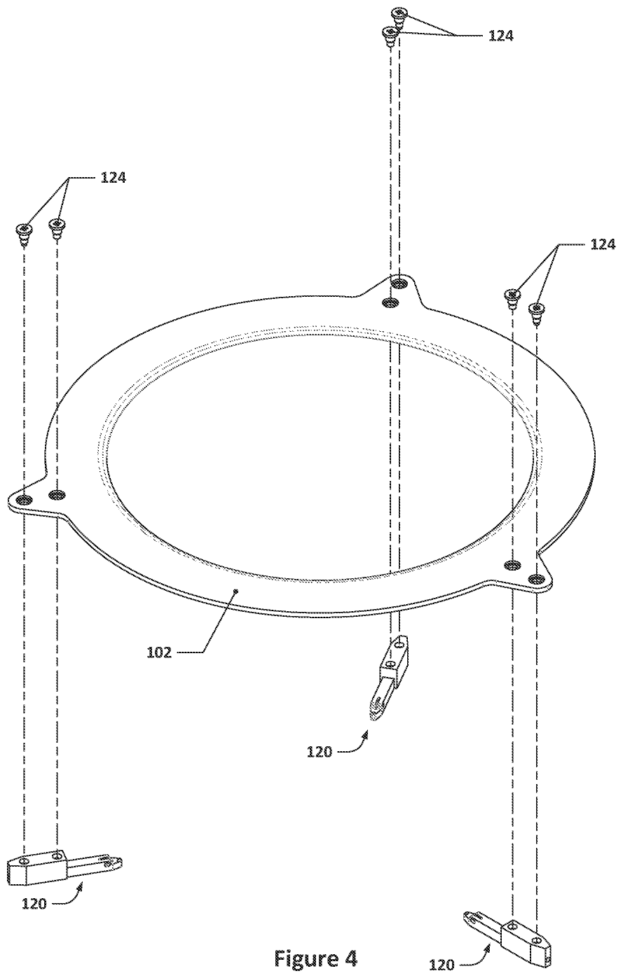

FIG. 4 is an exploded isometric view of the example edge ring of FIG. 1. As can be seen, the ring structure 102 and the roller mechanisms 120 are easily separable, e.g., by removing screws 124. It will be appreciated that one contemplated implementation of the mechanisms discussed herein is in the form of individual roller mechanisms 120, or a kit of multiple roller mechanisms 120 (or any of the other spring-biased roller mechanisms discussed herein) that may be used to upgrade a conventional edge ring (or repair an improved edge ring) for use in high-temperature differential processing conditions and/or processes having more stringent edge ring overlap requirements.

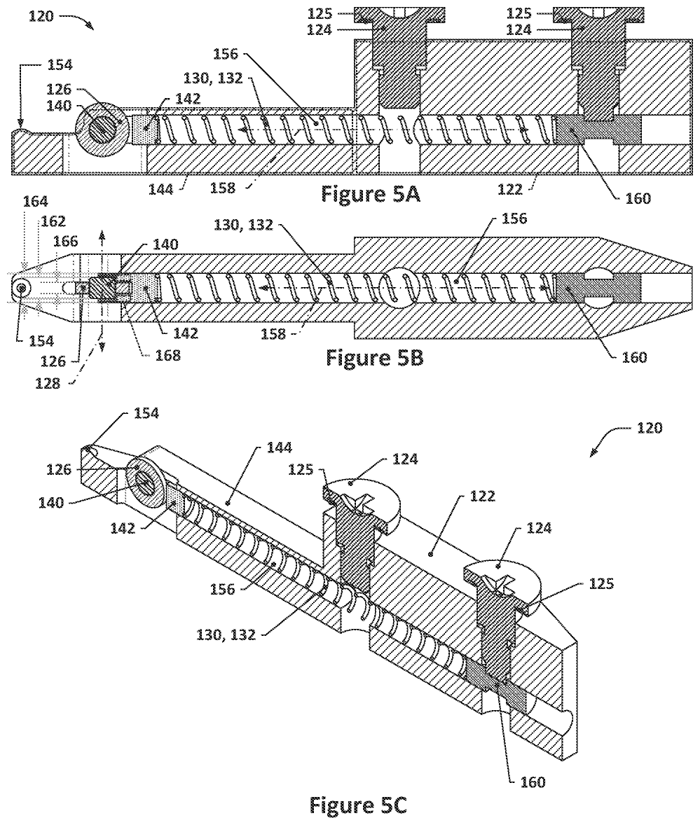

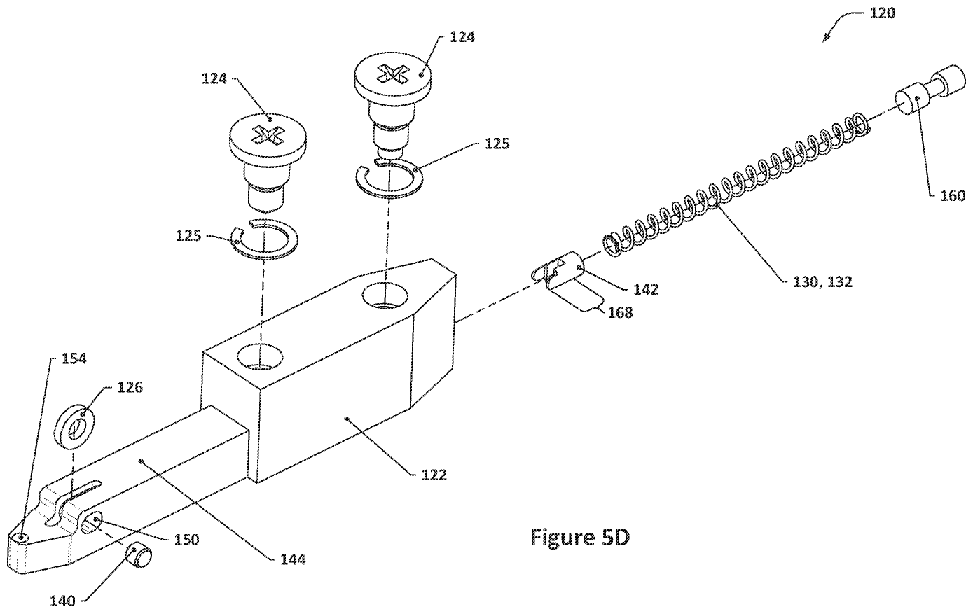

FIGS. 5A through 5D are a cross-sectional side view, a cross-sectional top view, an isometric section view, and an exploded isometric view, respectively, of an example roller mechanism for an edge ring.

As can be seen in FIGS. 5A through 5D, the roller mechanism 120 may include a non-compliant support structure 122 that connects with the ring structure 102 (not shown, although the screws 124 that would fasten the non-compliant support structure 122 to the ring structure 102 are shown as they would be if the ring structure 102 were present; washers 125 are also shown, which may be used to more evenly distribute the clamping load of the screws 124). The non-compliant support structure 122 may support a cantilever beam structure 144, or finger, that extends radially inward therefrom. It will be understood that the non-compliant support structure 122 and the cantilever beam structure 144 (as well as similar structures in other implementations discussed below) may generally be viewed as non-compliant or generally rigid in the context of the loads that such structures may typically experience during normal use of the edge ring and, in particular, when compared with the spring-biased rollers discussed later herein. The non-compliant support structure 122 may generally be sized and positioned such that the closest portions of at least two of the non-compliant support structures 122 for a given fully assembled edge ring are spaced apart by a distance that is greater than the diameter of the wafer 114 with which the edge ring is designed to be used. This allows the wafer 114 to be inserted radially between those non-compliant support structures 122 without touching either such non-compliant support structure 122. The cantilever beam structure 144 may have a first end that is connected with, extends from, or otherwise interfaced with the non-compliant support structure 122, and a second end that is located between the inner perimeter 104 of the ring structure 102 and the ring center axis 134 when the roller mechanism 120 is assembled to the ring structure 102. It will be understood that the cantilever beam structure 144 and the non-compliant support structure 122 may, as shown, be provided by a single integrated component or may, for example, be separate components or otherwise provided by multiple components that are fastened or joined together. The cantilever beam structure 144 may be offset from the underside of the ring structure 102 by a distance that is sufficient to provide clearance for a wafer handling robot end effector and wafer to be inserted into the edge ring, i.e., within the gap between the cantilever beam structure 144 and the underside of the ring structure 102. The non-compliant support structure 122 may thus act to provide the vertical gap between the cantilever beam structure 144 and the ring structure 102. It will be understood that both the non-compliant support structure 122 and the cantilever beam structure 144 may, in the context of this disclosure, generally be non-compliant, i.e., sufficiently stiff so as to not appreciably deflect during normal use. For the purposes of discussion, they may be considered to be rigid structures.

The second end of the cantilever beam structure 144 may include an axle 140, a roller 126, and a yoke 142. The axle 140 may be configured to support the roller 126 within the cantilever beam structure 144 and allow the roller 126 to rotate relative to the cantilever beam structure 144. An MCA 154 may be provided at the second end of the cantilever beam structure 144 at a location that is radially inboard of roller 126 relative to the ring center axis 112 when the roller mechanism 120 is assembled with the ring structure 102.

Unlike a roller mechanism for a conventional edge ring, the roller mechanism 120 includes additional features for spring-biasing the roller 126; roller mechanisms with such features may be thought of as providing “compliant wafer centering fingers,” as will become clear in the discussion below. In a conventional edge ring roller mechanism, the axle for the rollers is inserted through circular holes in both the roller and the cantilever beam structure 144, thereby fixing the axle and roller in place both radially and vertically relative to the ring center axis. In the cantilever beam structure 144 of the example roller mechanism 120, however, the axle 140 is inserted through a circular hole in the roller 126 but is passed through an obround (or otherwise elongate) hole or slot 150 (called out in FIG. 5D). The slot 150 may be relatively short, needing to only be long enough to accommodate the amount of radial travel that may be needed to accommodate the thermal expansion mismatch between the wafer and the edge ring, e.g., on the order of half a millimeter or so. It will be appreciated, of course, that longer lengths of slot 150 may be used as well, if desired. The slot 150 may serve to guide the axle 140 during radial translation thereof. For example, the slot 150 may have a length in a radial direction relative to the ring center axis 112 that is longer than a width of the slot 150 in a direction parallel to the ring center axis 112, and the width of the slot 150 may be sized to be slightly larger than the diameter or dimension of the axle 140 so as to allow the axle 140 to slide freely within the slot 150 in the radial direction (at least until the axle 140 reaches either end of the slot 150) while generally being prevented from translating in a direction parallel to the ring center axis 112 (aside from some small amount of translation to allow the axle 140 to move freely within the slot 150 without binding).

As can be further seen in FIGS. 5A through 5D, the roller mechanism 120 includes other features that are not present in roller mechanisms for conventional edge rings. For example, the roller mechanism 120 includes a bore 156 that extends along a bore axis 158, which may extend along a radial direction relative to the ring center axis 112 when the roller mechanism 120 is assembled with the ring structure 102. The bore 156 may be sized slightly larger in diameter (or size) than the yoke 142 so that the yoke 142 may slide radially within the bore 156. A spring element 130, which is a coil spring 132 in this case, may be housed within the bore 156 as well, and may be arranged so as to be compressed between the yoke 142 and a stopper 160. The stopper 160 may, for example, be held in place by one of the screws 124 or may, in some implementations, be a threaded plug, e.g., a socket head set screw, that may be threaded into a threaded interface at the exterior end of the bore 156.

The spring element 130 may act to push the yoke 142 into contact with the axle 140, thereby urging the axle 140 and the roller 126 that is rotatably supported thereby in a radially inward direction (it will be appreciated that references herein to a “radial” direction refer, unless indicated otherwise, to a direction that would be radial with respect to the ring center axis 112 when the roller mechanism in question is assembled with the ring structure 102). In this example, the yoke 142 may have two protruding portions 168 that may extend from the body of the yoke 142 and towards the axle 140. The protruding portions 168 may be spaced apart sufficiently that there is clearance for the roller 126 in between them. The protruding portions 168 may also have steps in them that contact the axle 140 to allow the yoke 142 to transmit the load from the spring element 130 to the axle 140. The protruding portions 168 may also have portions that extend beyond the steps that contact the axle 140 and that bracket the axle 140 on either side, thus capturing the axle 140 in between them. These additional portions may prevent the axle from sliding out along its axis of rotation.

When a downward force is applied to the roller 126 at a location radially inboard of the axis of rotation 128 of the roller 126, this causes some component of that downward force to be transferred to the axle 140 along a radially outward direction, thereby pushing back the yoke 142 against the spring element 130 and compressing it (or compressing it further). Thus, when a wafer 114 is placed such that the outer edge of the wafer 114 rests on one of the rollers, the weight of the wafer may act to push the roller 126 radially outwards. At the same time, the spring element 130 may act to push the wafer radially inwards. This may, in turn, cause the wafer 114 to transmit some of the spring force to the rollers 126 of the other roller mechanisms 120, causing radial displacement of those rollers 126 as well. Eventually, the spring elements 130 of all of the roller mechanisms 120 of such an edge ring may reach a state of equilibrium where each roller 126 is displaced radially outward by a substantially similar amount, thereby centering the wafer 114 relative to the ring structure 102.

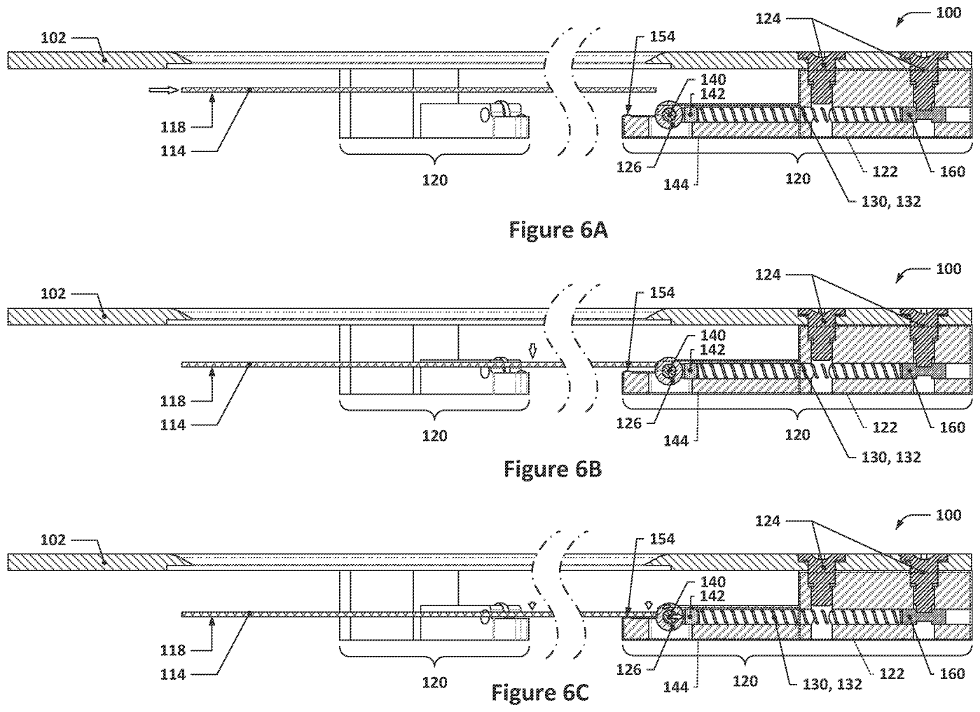

The engagement of the roller mechanism 120 with the wafer 114 is discussed in more detail below with respect to FIGS. 6A through 6C. FIGS. 6A through 6C depict cross-sectional broken side views of the edge ring of FIG. 1 during various stages of wafer placement in the edge ring.

In order to be suitably large enough to see various details, FIGS. 6A through 6C omit portions of the ring structure 102 and wafer 114 between the indicated break lines (wavy dash-dot-dash lines) and show the depicted portions of the edge ring on either side of the break lines as closer together than they actually are.

In FIG. 6A, the wafer 114 has been inserted from the left, e.g., by a wafer handling robot, into the space between the cantilever beam structure 144 and the ring structure 102. A section view of one of the roller mechanisms 120 is shown, with another roller mechanism 120 shown in the background; the wafer 114 passes between the roller mechanism 120 shown in the background and a third roller mechanism 120 (not shown) which would be on an opposite side of the ring structure 102 therefrom.

As can be seen, the wafer 114 is clear of the cantilever beam structure 144 and the rollers 126 during the insertion operation due to the vertical gap provided by the height of the non-compliant support structure 122. After insertion, the wafer 114 and the apparatus 100, i.e., the edge ring, may be caused to undergo relative vertical movement such that the underside 118 of the wafer 114 approaches the MCAs 154, as shown in FIG. 6B. This may be accomplished by lowering the wafer 114 relative to the apparatus 100, raising the apparatus 100 relative to the wafer 114, or both lowering the wafer 114 relative to the apparatus 100 and raising the apparatus 100 relative to the wafer 114.

In FIG. 6B, the outer bottom edge of the wafer 114 has contacted the rollers 126, at which point the rollers 126 will take the load of the wafer 114 from whatever structure, e.g., the end effector of the wafer handling robot or lift pins of a chuck that may have been used to lift the wafer 114 off of the end effector of the wafer handling robot after the wafer 114 was inserted into the edge ring as shown in FIG. 6A, has been supporting the wafer 114 during the vertical displacement of the wafer 114 and the edge ring relative to each other.

At this point, the weight of the wafer 114 may cause the rollers 126 that are in contact with the wafer 114 to rotate about their respective axes of rotation 128 (in FIG. 6B, the rotation of the sectioned roller 126 on the right is in the counterclockwise direction. At the same time, the weight of the wafer 114 may exert a radial force component on the roller 126, and thus the axle 140, the yoke 142, and the spring element 130 that causes the spring element 130 to compress slightly. Eventually, the rollers 126 will have moved sufficiently radially outward that the wafer 114 is able to continue its downward movement relative to the edge ring and reach the MCAs 154, upon which the wafer 114 will come to rest on the MCAs 154 in a position that is centered on the ring structure 102.

It will be noted that if the spring elements 130 are selected to be generally the same and if the roller mechanisms 120 are generally configured the same, the spring elements 130 will act to center the wafer 114 relative to the ring structure 102. For example, if the wafer 114 is off-center such that a roller 126 of one of the roller mechanisms 126 is pushed radially outward by the wafer 114 to a greater extent than the rollers 126 of the other roller mechanisms 120, the spring element 130 associated with the more-displaced roller 126 may be compressed to a further extent than the spring elements 130 of the other roller mechanisms 120. This increased compression, in turn, causes the spring element 130 to exert more radial force in the inward direction than the spring elements 130 of the other roller mechanisms 126. The more-compressed spring element 130 will thus act to push the wafer 114 towards the center of the ring structure 102, thereby causing the spring elements 130 associated with the other roller mechanisms 120 to be further compressed. Eventually, the spring elements 130 will reach equilibrium with each other, and the wafer 114 will thereby be positioned in a generally centered manner relative to the edge ring.

It will be appreciated that the implementation of a roller mechanism with a spring-biased roller may be implemented in a number of different ways while still preserving the overall form factor of a roller mechanism for a conventional edge ring. Two further implementations of a roller mechanism with spring-biased rollers for edge rings are discussed below.

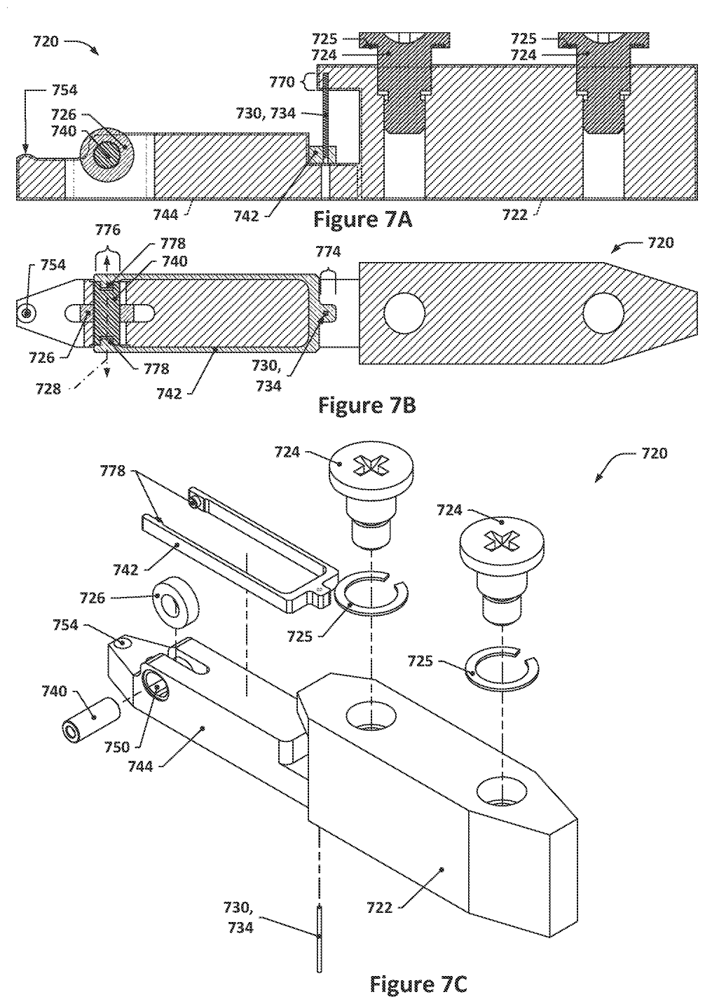

FIGS. 7A through 7C are a cross-sectional side view, a cross-sectional top view, and an exploded isometric view, respectively, of another example roller mechanism for an edge ring. In FIGS. 7A through 7C, a roller mechanism 720 is shown which includes, as with the roller mechanism 120, a non-compliant support structure 722 and a cantilever beam structure 744. Screws 724 and washers 725 for affixing the non-compliant support structure 722 to the ring structure 102 (not shown) are indicated, as well as an MCA 754, roller 726, and axle 740.

The roller mechanism 720 further includes a yoke 742, which is somewhat different from the yoke 142 discussed earlier, although the purposes of both yokes 142 and 742 are similar in that they act to convey the spring force exerted by a spring element 130 or 730 (a beam spring 734, in this example) to the axle 140 or 740 and thus to the roller 126 or 726. The yoke 742 in FIG. 7 has two elongate portions that are joined together by a transverse segment near the non-compliant support structure 722. The transverse section of the yoke 742 may have portion that serves as a first end 774 of the yoke 742, and the elongate portions of the yoke 742 may have portions that serve as the second end 776 of the yoke 742. The second end 776 of the yoke 742 may include axle interfaces 778, which may be mechanical interfaces that allow for radial loads from the yoke 742 to be transmitted to the axle 740 and thus the roller 726. In some implementations, the axle interfaces 778 may be configured to allow the roller 726 to rotate relative to the yoke 742. As with the axle 140, the axle 740 may be configured to be translatable within a slot 750 so as to constrain the movement of the roller 726 to only rotation and radial translation.

The first end of the yoke 742 may be interfaced with the spring element 730, which, in this example, is a cantilevered beam spring 734, e.g., a rod or a tube. The cantilevered beam spring 734 may be simply supported by one or both of the non-compliant support structure 722 and the yoke 742. For example, the non-compliant support structure 722 may include an overhang or ledge (as shown) having a hole drilled in it that is sized slightly smaller than a diameter of the cantilever beam spring 734 such that the cantilever beam spring 734 is subjected to a light press fit when inserted into the hole. The yoke 742 may correspondingly have a hole drilled in it that is either the same size as, or slightly larger than, the hole in the non-compliant support structure 722. The cantilevered beam spring may extend into the hole in the yoke 742 and transmit lateral loads (or receive them) through contact with the walls of such a hole.

When radial displacement of the yoke 742 occurs, this causes the cantilevered beam spring 734 to deflect, resisting the radial displacement in a manner similar to the coil spring 132 discussed earlier.

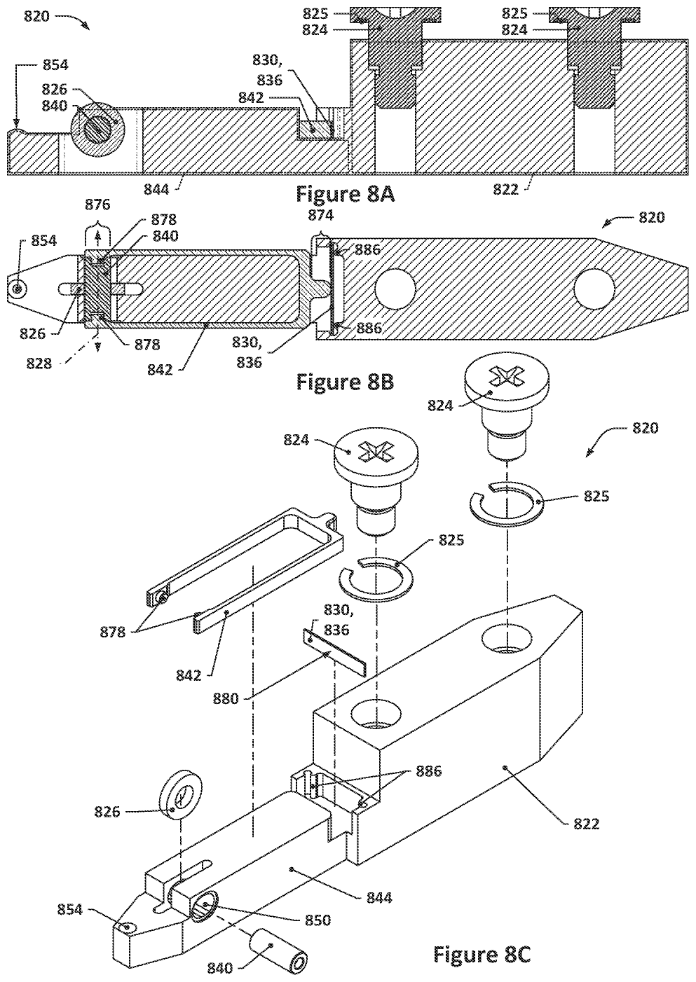

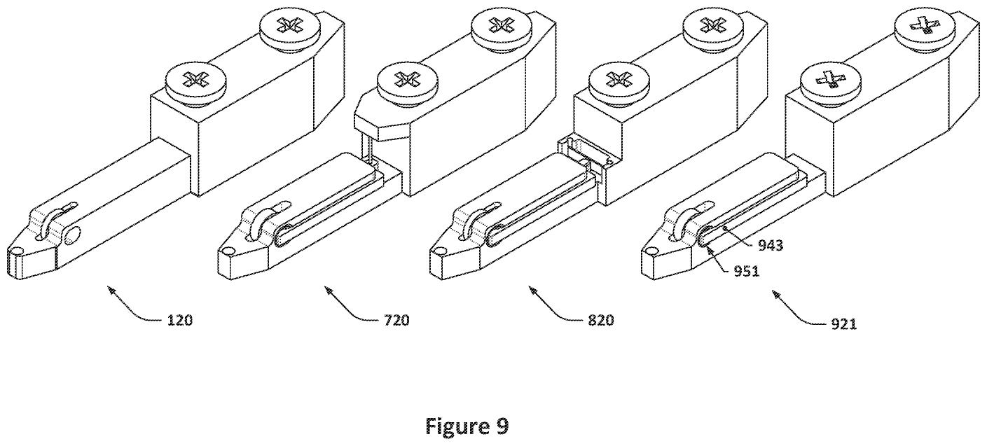

FIGS. 8A through 8C are a cross-sectional side view, a cross-sectional top view, and an exploded isometric view, respectively, of yet another example roller mechanism for an edge ring. In FIGS. 8A through 8C, a roller mechanism 820 is shown which includes, as with the roller mechanism 720, a non-compliant support structure 822 and a cantilever beam structure 844. Screws 824 and washers 825 for affixing the non-compliant support structure 822 to the ring structure 702 (not shown) are indicated, as well as an MCA 854, roller 826, and axle 840.

The roller mechanism 820 further includes a yoke 842, which is similar to the yoke 742 discussed earlier, which has two elongate portions that are joined together by a transverse segment near the non-compliant support structure 822. The transverse section of the yoke 842 may have portion that serves as a first end 874 of the yoke 842, and the elongate portions of the yoke 842 may have portions that serve as the second end 876 of the yoke 842. The second end 876 of the yoke 842 may include axle interfaces 878, which may be mechanical interfaces that allow for radial loads from the yoke 842 to be transmitted to the axle 840 and thus the roller 826. In some implementations, the axle interfaces 878 may be configured to allow the roller 826 to rotate relative to the yoke 842. As with the axle 740, the axle 840 may be configured to be translatable within a slot 850 so as to constrain the movement of the roller 826 to only rotation and radial translation.

The first end of the yoke 842 may be interfaced with the spring element 830, which, in this example, is a leaf spring 836, e.g., a generally flat (some curvature may be present in some such implementations), thin plate which is supported at two opposing ends such that the major face 880 of the leaf spring 836 is generally parallel to the ring center axis 112. The leaf spring 836 may be simply supported at two opposing ends by support features 886 that are fixed with respect to the non-compliant support structure 722. When radial displacement of the yoke 842 occurs, this causes the first end 774 of the yoke 742 to apply a force to the middle of the leaf spring 736. This causes the leaf spring 836 to bulge radially outward and to exert a countering force radially inward, thereby urging the roller 826 radially inward.

It will be appreciated that the additional components of the roller mechanisms 120, 720, and 820 may, as shown and discussed above, be implemented in a manner that leaves such roller mechanisms being generally of the same overall shape and size, e.g., similar to that of a roller mechanism for a conventional edge ring. To illustrate this commonality, FIG. 9 depicts four different roller mechanisms—the three roller mechanisms 120, 720, and 820 discussed above, as well as a roller mechanism 921 for a conventional edge ring. It will be noted that the yoke-like structure 943 in the roller mechanism 921 does not have axle interfaces, such as axle interfaces 778 or 878. Instead, the structure 943 simply serves to retain the axle of the roller mechanism 921 from slipping out of the hole 951 laterally, e.g., along the axis of rotation of the axle. No radial load transfer occurs between the structure 943 and the axle of the roller mechanism 921. In another point of distinction, it will be further observed that the hole 951 is circular as compared with the slots 150, 750, and 750 discussed above, thus preventing the axle and roller for the roller mechanism 921 from translating radially.

edge rings featuring roller mechanisms discussed herein may be made of materials typically used for edge rings, e.g., aluminum oxide, aluminum nitride, silicon oxide, silicon nitride, quartz, or other materials that are chemically resistant and other wise appropriate for use in semiconductor processing environments. Aluminum oxide or single-crystal aluminum oxide, i.e., sapphire, may be particularly well suited for use with some of the components, e.g., the axles, wheels, yokes, and/or spring elements due to its resistance to the corrosive environments present in many semiconductor processing chambers, high hardness and wear resistance, low friction, and resilience. Other materials may be used as well, including, in some instances, nickel-dominant alloys, pure nickel, or other metals with high resistance to corrosive environments that may be found in semiconductor processing chambers. In particular, the spring elements used, due to the repeated flexure that they may undergo, may be made of such a metal-based material in order to reduce the likelihood of breakage, although such implementations may be more prone to corrosion compared to similar implementations using ceramic materials in place of metal ones.

It is to be understood that the phrases “for each <item> of the one or more <items>,” “each <item> of the one or more <items>,” or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite the fact that dictionary definitions of “each” frequently define the term to refer to “every one of two or more things”) and would not imply that there must be at least two of those items. Similarly, the term “set” or “subset” should not be viewed, in itself, as necessarily encompassing a plurality of items—it will be understood that a set or a subset can encompass only one member or multiple members (unless the context indicates otherwise).

The use, if any, of ordinal indicators, e.g., (a), (b), (c) . . . or the like, in this disclosure and claims is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated) unless indicated otherwise. For example, if step (ii) involves the handling of an element that is created in step (i), then step (ii) may be viewed as happening at some point after step (i). Similarly, if step (i) involves the handling of an element that is created in step (ii), the reverse is to be understood.

Terms such as “about,” “approximately,” “substantially,” “nominal,” or the like, when used in reference to quantities or similar quantifiable properties, are to be understood to be inclusive of values within ±10% of the values or relationship specified (as well as inclusive of the actual values or relationship specified), unless otherwise indicated.

It should be appreciated that all combinations of the foregoing concepts (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

It is to be further understood that the above disclosure, while focusing on a particular example implementation or implementations, is not limited to only the discussed example, but may also apply to similar variants and mechanisms as well, and such similar variants and mechanisms are also considered to be within the scope of this disclosure.

What is claimed is:

1. An apparatus comprising:
a ring structure having a circular opening defining a ring center axis; and
a plurality of roller mechanisms that are connected with the ring structure, each roller mechanism having:
a) a non-compliant support structure,
b) an axle,
c) a roller configured to rotate about a corresponding axis of rotation relative to the non-compliant support structure of that roller mechanism and supported by the axle of that roller mechanism within that roller mechanism,
d) a cantilever beam structure extending inward from the non-compliant support structure of that roller mechanism towards the ring center axis, wherein:
the cantilever beam structure of that roller mechanism has a slot at a radially inward end and having length along a radial direction relative to the ring center axis and a width along a direction parallel to the ring center axis,
the length of the slot of that roller mechanism is larger than the width of the slot of that roller mechanism, and
the width of the slot of that roller mechanism is larger than a portion of the axle of that roller mechanism located therein, and
e) a spring element configured to urge the axle for that roller mechanism toward the ring center axis, wherein the roller of that roller mechanism is positioned so as to not overlap with the ring structure when viewed along an axis perpendicular to the ring center axis.

2. The apparatus of claim 1, wherein the spring element of each roller mechanism is a coil spring.

3. The apparatus of claim 1, wherein the spring element of each roller mechanism is a cantilevered beam spring.

4. The apparatus of claim 1, wherein the spring element of each roller mechanism is a leaf spring.

5. The apparatus of claim 1, wherein:
the minimum distance between the non-compliant support structures of at least two of the roller mechanisms is larger than a first distance,
the circular opening has a diameter that is less than the first distance, and
the first distance is selected from the group consisting of: 200 mm, 300 mm, and 450 mm.

6. The apparatus of claim 1, wherein the rollers are all positioned entirely outside of the circular opening when viewed along the ring center axis.

7. The apparatus of claim 1, wherein there are three roller mechanisms that are spaced at locations 120°±10° apart from one another about the ring center axis.

8. The apparatus of claim 1, wherein each roller mechanism further includes a yoke, wherein:
the yoke of that roller mechanism engages the axle of that roller mechanism, and
the spring element of that roller mechanism is configured to apply a force to the yoke of that roller mechanism that urges the yoke of that roller mechanism, and thus the axle of that roller mechanism and the roller of that roller mechanism, towards the ring center axis.

9. The apparatus of claim 8, wherein each roller mechanism further includes a cantilever beam spring and, for each roller mechanism:
a first end of the cantilever beam spring of that roller mechanism is interfaced with a portion of the non-compliant support structure of that roller mechanism,
a second end of the cantilever beam spring of that roller mechanism is interfaced with the yoke of that roller mechanism, and
the cantilever beam spring of that roller mechanism is configured to bend when the yoke of that roller mechanism is translated away from the ring center axis.

10. The apparatus of claim 8, wherein each roller mechanism further includes a leaf spring and, for each roller mechanism, the yoke of that roller mechanism has a first end that is positioned so as to deflect the leaf spring of that roller mechanism when the yoke of that roller mechanism is translated radially outward relative to the ring center axis.

11. The apparatus of claim 8, wherein, for each roller mechanism:
a first side of the leaf spring of that roller mechanism is supported by two spaced-apart support features of that roller mechanism, and
the first end of the yoke of that roller mechanism is configured to contact a second side of the leaf spring of that roller mechanism opposite the first side of that leaf spring at a location midway between the spaced-apart support features of that roller mechanism.

12. The apparatus of claim 9, wherein the cantilever beam spring is a hollow tube.

13. The apparatus of claim 9, wherein the cantilever beam spring is a ceramic capillary tube.

14. The apparatus of claim 9, wherein, for each roller mechanism:
the cantilever beam spring of that roller mechanism is interfaced with a first end of the yoke of that roller mechanism, and
a second end of the yoke of that roller mechanism opposite the first end of the yoke of that roller mechanism includes an axle interface that is configured to rotatably support the axle of that roller mechanism.

15. The apparatus of claim 1, wherein, for each roller mechanism:
the cantilever beam structure of that roller mechanism has a minimum contact area feature disposed at an end thereof that is closest to the ring center axis, and
the minimum contact area feature of the cantilever beam structure of that roller mechanism is located closer to the ring center axis than the roller of that roller mechanism.

16. The apparatus of claim 1, wherein, for each roller mechanism:
at least the cantilever beam structure of that roller mechanism includes a corresponding bore that extends along a corresponding bore axis that extends along a radial direction relative to the ring center axis, and
the spring element of that roller mechanism is a coil spring that is located at least partially within the bore.

17. The apparatus of claim 16, wherein, for each roller mechanism:
the axle for that roller mechanism has a length along the corresponding axis of rotation for the roller of that roller mechanism that is less than a width of the yoke for that roller mechanism along the corresponding axis of rotation for the roller for that roller mechanism,
the roller for that roller mechanism has a width along the corresponding axis of rotation of that roller that is less than the width of the yoke for that roller mechanism along the corresponding axis of rotation of that roller,
the yoke for that roller mechanism has two protruding portions that overlap both the roller and the axle for that roller mechanism when viewed along the corresponding axis of rotation for the roller of that roller mechanism, and
both the roller and the axle for that roller mechanism are interposed between the two protruding portions of the yoke for that roller mechanism.

18. The apparatus of claim 16, wherein the coil spring is made of nickel or a nickel-dominant alloy.

19. The apparatus of claim 16, wherein the coil spring is made of a ceramic material.
